(19) United States
(12) Patent Application Publication
(10) Pub. No.: US 2012/0106172 A1
(43) Pub. Date: May 3, 2012

(54) Encapsulating method for sealed and water-proof LED and luminescent holder

(76) Inventor: Cai Jun Hao, Guangdong Province (CN)

(21) Appl. No.: 12/915,058

(22) Filed: Oct. 29, 2010

(51) Int. Cl. H01L 33/48; H01L 21/50

(52) U.S. Cl. 362/368; 438/26; 257/E33.058; 257/E21.499

(57) ABSTRACT

This invention relates to an encapsulating method for sealed and water-proof LED, comprising the following steps: separately weld two leads or three leads onto the two pins of the LED; molding by mould and used for installing the holder of LED; put the LED with lead or various types of ornaments into the holder; buckle the holder; weld the periphery of the buckled holder by ultrasonic machine to form a sealed luminescent light. By means of welding the lead of the luminotron first, putting it into the holder later, and finally sealing it by ultrasonic machine, it can increase the up-to-standard rate and reduce the rejections on the premise of ensuring the sealing effect.

### BACKGROUND OF THE INVENTION

This invention relates to the method of making string lights by LED, specifically relates to an encapsulating method for sealed and water-proof LED and luminescent light made by this method.

In prior art, there is a luminescent string lights. Each luminescent light is composed of LED and holder. Generally, it is switched into conduction after connecting the pin of the luminotron and the shrapnel in the holder. The shrapnel is connected to the power through lead. Since the string lights are normally used outside, the holder is not water-proof and the pin and the shrapnel are not fixed together, the LED may be poor in conductance or damaged if water enters the holder.

There is another method that is to directly encapsulate the LED and the holder together by means of one-off injection moulding. Although this method is water-proof, the rate of finished products is low and the amount of rejections increases.

### BRIEF SUMMARY OF THE INVENTION

The objective of the present invention is to overcome the shortcomings in existing technology and to provide an encapsulating method for sealed and water-proof LED and luminescent light. The luminescent light made by this method is low in cost and rejections. Moreover, it is superior in water-proof performance and will not be damaged even though it is used outside for a long time.

Provide an encapsulating method for sealed and water-proof LED, including the following steps:

Separately weld two leads or three leads onto the two pins of the LED;

Molding by mould and used for installing the holder of LED;

Put the LED with lead or various types of ornaments into the holder;

Buckle the holder;

Weld the periphery of the buckled holder by ultrasonic machine to form a sealed luminescent light.

This invention enjoys such advantages as the followings: By means of welding the lead of the luminotron first, putting it into the holder later, and finally sealing it by ultrasonic machine, it can increase the up-to-standard rate and reduce the rejections on the premise of ensuring the sealing effect.

The holder can adopt folding structure which is to set a folding structure on one side only. It can also use two same hemi-structures which have buckle structure. The pin of the LED can be directly welded on the holder. Its luminescent end comes out from one end of the holder after installing the LED. The other two or three leads separately come out from the two holes of the other end, and then the periphery of the two hemi-components is welded together by the ultrasonic plastic soldering technique, so as to form a complete sealed holder. In this way, the rain could not immerge into it. As the LED and the lead are directly welded, damage by immerged water and poor conductance are avoided.

### BRIEF DESCRIPTION OF THE DRAWINGS

FIG. 1 is the structure profile of one hemi-structure in Implementation Example One of holder of sealed and water-proof luminescent light made by this method.

FIG. 2 is lateral view of FIG. 1.

FIG. 3 is structure chart of sealed and water-proof luminescent holder.

### DETAILED DESCRIPTION OF THE INVENTION

Provide an encapsulating method for sealed and water-proof LED, including the following steps: separately weld two leads or three leads onto the two pins of the LED; molding by mould and used for installing the holder of LED; put the LED with lead or various types of ornaments into the holder; buckle the holder; weld the periphery of the buckled holder by ultrasonic machine to form a sealed luminescent light.

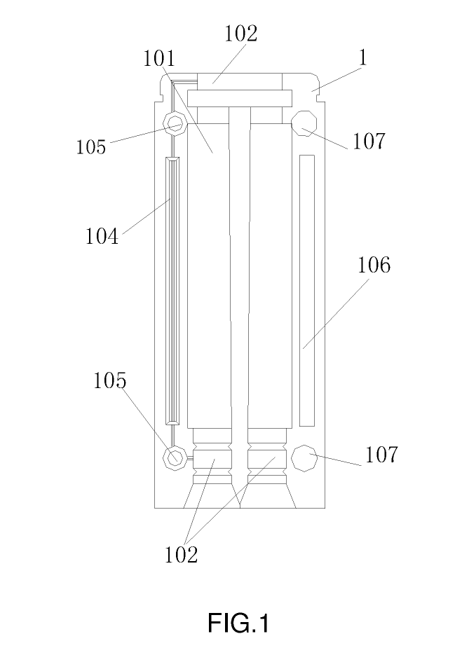

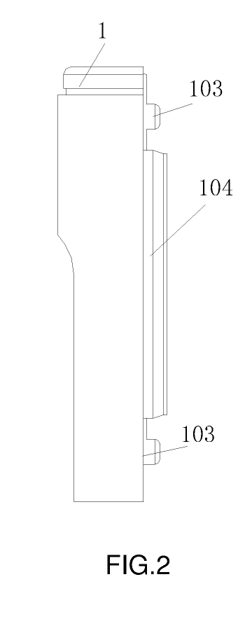

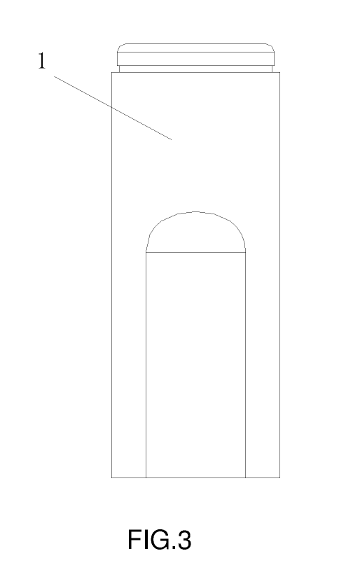

As shown in FIGS. 1, 2 and 3, it provides a sealed and water-proof luminescent holder which is composed of two hemi-components 1 buckled together. After the two hemi-components buckled together, there forms a chamber inside. One end forms a hole for inserting the LED and the other end forms two separate holes for the two or three leads of the LED to get through.

As shown in FIG. 1, the two hemi-components 1 are structured in semi-column whose inside is a cavity 101. One end is a semicircular orifice 102 and the other end is two small separate semicircular orifices 103. One lateral surface of the semi-column is equipped with a strip 104 which is set with one bayoner lock 105 separately on its two ends. The other lateral surface is installed with slot 106 and hole 107 for said strip 104 and bayoner lock 105. The two hemi-components form a column holder after connected by the strip 104 and slot 106 and bayoner lock 105 and hole 107.

The periphery of the two hemi-components is welded together by the ultrasonic plastic soldering technique, so as to form a complete sealed holder. In this way, the rain could not immerge into it. As the LED and the lead are directly welded, damage by immerged water and poor conductance are avoided.

What is claimed is:

1. An encapsulating method for sealed and water-proof LED, comprising the following steps:
1) separately weld two leads or three leads onto the two pins of the LED;
2) molding by mould and used for installing the holder of LED;
3) put the LED with lead or various types of ornaments into the holder;
4) buckle the holder;
5) Weld the periphery of the buckled holder by ultrasonic machine to form a sealed luminescent light.

2. A sealed and water-proof luminescent holder adopting the method as set forth in claim 1, characterized in that it is composed by two hemi-components buckled together; after the two hemi-components buckled together, there forms a chamber inside; one end forms a hole for inserting the LED and the other end forms two separate holes for the two or three leads of the LED to get through.

3. The sealed and water-proof luminescent holder as set forth in claim 2, characterized in that the said hemi-component is structured in semi-column whose inside is a cavity; on one end is a semicircular orifice and on the other end are two small separate semicircular orifices; one lateral surface of the semi-column is equipped with a strip which is set with one bayoner lock separately on its two ends; the other lateral surface is installed with slot and hole for said strip and bayoner lock; the two hemi-components form a column holder after connected by the strip and bayoner lock.
